(19) United States
(12) Patent Application Publication
(10) Pub. No.: US 2011/0102722 A1
(43) Pub. Date: May 5, 2011

(54) INDIUM TIN OXIDE SPUTTERING TARGET AND TRANSPARENT CONDUCTIVE FILM FABRICATED USING THE SAME

(75) Inventors: Shin Hyuk KANG, ChungCheongNam-Do (KR); Jun Ho CHOI, ChungCheongNam-Do (KR); Hwang Yong GO, ChungCheongNam-Do (KR); Sang Cheol JUNG, ChungCheongNam-Do (KR)

(73) Assignee: SAMSUNG CORNING PRECISION MATERIALS CO., LTD.

(21) Appl. No.: 12/915,899

(22) Filed: Oct. 29, 2010

(30) Foreign Application Priority Data
Oct. 30, 2009 (KR) 10-2009-0103886

(51) Int. Cl. G02F 1/1343; C23C 14/08; C23C 14/35; H01B 1/02

(52) U.S. Cl. 349/139; 204/298.13; 204/192.29; 252/520.1

(57) ABSTRACT

An indium tin oxide sputtering target includes indium oxide, tin oxide, and gallium. The content of tin atoms is 5 to 15 atomic percent of the total amount of indium and tin atoms, and the content of gallium atoms is 0.5 to 7 atomic percent of the total amount of indium, tin, and gallium atoms. A method of fabricating an indium tin oxide transparent conductive film includes depositing the transparent conductive film by sputtering the sputtering target. The indium tin oxide transparent conductive film having high durability can be fabricated by depositing an amorphous transparent conductive film by sputtering the sputtering target at a first temperature, patterning the deposited amorphous transparent conductive film by etching it using a weak acid, and crystallizing the patterned amorphous transparent conductive film at a second temperature higher than the first temperature. A crystallization temperature ranges from 150° C. to 210° C., or from 170° C. to 210° C.

### CROSS REFERENCE TO RELATED APPLICATION

The present application claims priority from Korean Patent Application Number 10-2009-0103886 filed on Oct. 30, 2009, the entire contents of which application are incorporated herein for all purposes by this reference.

### BACKGROUND OF THE INVENTION

1. Field of the Invention

The present invention relates to an Indium Tin Oxide (ITO) target and a transparent conductive film fabricated using the same, and more particularly, to an ITO target that has excellent optical and electrical characteristics and etchability, and to a transparent sputtering target.

2. Description of Related Art

An ITO film made of tin-doped indium oxide is widely used as a transparent conductive film, which is a typical electrode material for a flat panel display, such as a Liquid Crystal Display (LCD), a Plasma Display Panel (PDP), an Electroluminescent Display (ELD), or the like, and for a solar cell. The ITO film has the advantages not only of excellent transparency and conductivity, but also of etchability and excellent adhesiveness to a substrate.

After the ITO film is formed, it is etched using a strong acid, aqua regia, or the like during the formation of a circuit pattern. However, aluminum, which is used as the wiring material for a Thin Film Transistor (TFT), is vulnerable to corrosion. Therefore, there is a demand for a transparent conductive film that can be etched without having an adverse effect on the wiring material.

In response to this demand, an attempt to form an amorphous ITO film having excellent etching characteristics was proposed. It became possible to form an amorphous ITO film by using hydrogen or water together with a source gas at a low temperature during the formation of the film, and to etch the amorphous ITO film using weak acid, thereby improving the patterning characteristics and preventing the underlying wiring from being corroded. However, this method has problems in that hydrogen or water supplied during sputtering causes abnormal discharge, which in turn forms abnormal protuberances called “nodules” on an ITO target and triggers the formation of cohered impurity that cause localized high resistance to the film. In addition, decreased adhesiveness to the substrate, increased contact resistance, etching residue, or the like have also been reported.

According to another attempt, Indium Zinc Oxide (IZO) was proposed as a target material for forming an amorphous film. However, this material does not have good specific resistance or transmissivity compared to ITO, and is known to be expensive. Furthermore, since IZO is dissolved by an etching agent for aluminum, it is difficult to use IZO when a construction in which a reflecting electrode is formed on the transparent electrode is employed.

The information disclosed in this Background of the Invention section is only for the enhancement of understanding of the background of the invention, and should not be taken as an acknowledgment or any form of suggestion that this information forms a prior art that would already be known to a person skilled in the art.

### BRIEF SUMMARY OF THE INVENTION

Various aspects of the present invention provide a transparent conductive film that has excellent etchability, so that it causes neither an underlying material nor other materials to be corroded and does not cause problems such as residue, and a sputtering target that can form the transparent conductive film.

Also provided is an Indium Tin Oxide (ITO) transparent conductive film that exhibits excellent electrical and optical characteristics due to low specific resistance and high transmissivity, and a sputtering target that can form the transparent conductive film.

In an aspect of the present invention, provided is an indium tin oxide sputtering target includes indium oxide, tin oxide, and gallium, in which the content of tin atoms is 5 to 15 atomic percent of the total amount of indium and tin atoms, and the content of gallium atoms is 0.5 to 7 atomic percent of the total amount of indium, tin, and gallium atoms.

In another aspect of the present invention, also provided is a method of fabricating an indium tin oxide transparent conductive film, the method includes depositing the transparent conductive film by sputtering the above-described sputtering target. The indium tin oxide transparent conductive film having high durability can be fabricated by depositing an amorphous transparent conductive film by sputtering the sputtering target at a first temperature, patterning the deposited amorphous transparent conductive film by etching it using a weak acid, and crystallizing the patterned amorphous transparent conductive film at a second temperature higher than the first temperature.

In a further aspect of the invention, also provided is an indium tin oxide transparent conductive film that has a crystallization temperature ranging from 150° C. to 210° C., or from 170° C. to 210° C.

In yet another aspect of the invention, also provided is a Liquid Crystal Display (LCD) that includes a transparent electrode made of the above-described indium tin oxide transparent conductive film.

According to exemplary embodiments of the invention, the transparent conductive film can be etched using a weak acid and thus prevent the underlying wiring from being corroded and etching residue from occurring, which would otherwise be inevitably produced in a transparent conductive film from a target of the related art by a strong acid. In addition, the transparent conductive film according to exemplary embodiments of the invention has low specific resistance and excellent light transmissivity.

Excellent etchability characteristics are achieved since the film is etched in an amorphous state during the etching step in the TFT-array process for an LCD, and low resistance and high durability characteristics are realized through crystallization during the subsequent heat treatment process. Therefore, the transparent conductive film according to exemplary embodiments of the invention can be used as transparent electrodes for a variety of display devices such as an LCD that require high durability and low resistance.

The methods and apparatuses of the present invention have other features and advantages which will be apparent from, or are set forth in more detail in the accompanying drawings, which are incorporated herein, and in the following Detailed Description of the Invention, which together serve to explain certain principles of the present invention.

### BRIEF DESCRIPTION OF THE DRAWINGS

FIG. 1 is a graph showing an XRD analysis result of a transparent conductive film according to an exemplary embodiment of the invention;

FIG. 2 is a graph showing an XRD analysis result of a transparent conductive film according to Comparative Example 1;

FIG. 3 is a graph showing an XRD analysis result of a transparent conductive film according to Comparative Example 2;

FIG. 4 is a graph showing changes in the specific resistances of transparent conductive films depending on the content of gallium in ITO sputtering targets;

FIG. 5 is a graph showing an XRD analysis result of a transparent conductive film fabricated from a target that contains 3 atomic percent of gallium;

FIG. 6 is a graph showing an XRD analysis result of a transparent conductive film fabricated from a target that contains 6.5 atomic percent of gallium; and

FIG. 7 is a schematic view showing a process of fabricating an LCD that has a transparent conductive film according to an exemplary embodiment of the invention as a transparent electrode.

### DETAILED DESCRIPTION OF THE INVENTION

Reference will now be made in detail to various embodiments of the present invention(s), examples of which are illustrated in the accompanying drawings and described below. While the invention(s) will be described in conjunction with exemplary embodiments, it will be understood that the present description is not intended to limit the invention(s) to those exemplary embodiments. On the contrary, the invention(s) is/are intended to cover not only the exemplary embodiments, but also various alternatives, modifications, equivalents and other embodiments that may be included within the spirit and scope of the invention as defined by the appended claims.

An ITO sputtering target according to an exemplary embodiment of the invention includes indium oxide (In₂O₃), tin oxide (SnO₂), and gallium.

The content of tin atoms is preferably from 5 to 15 atomic percent, more preferably from 7 to 10 atomic percent, and still more preferably from 9 to 10 atomic percent of the total amount of indium atoms and tin atoms.

ITO is doped with gallium in the form of pure gallium or a gallium compound (e.g., a gallium oxide). Here, the content of gallium atoms is preferably from 0.5 to 7 atomic percent, and more preferably from 3 to 6.5 atomic percent of the total amount of indium, tin, and gallium atoms.

In an exemplary embodiment, the sputtering target of this embodiment can be fabricated through the step of preparing a slurry mixture, the step of producing particulate powder by wet milling and drying the slurry mixture, the step of producing a compact by pressing the particulate powder, and the step of sintering the compact.

A transparent conductive film deposited using the sputtering target has excellent etchability in the amorphous state, and the phase thereof changes from an amorphous to a crystalline state preferably at a temperature ranging from 150° C. to 210° C., or from 170° C. to 210° C., and thereby domain structure is formed. That is, in exemplary embodiments of the invention, it is preferred that the crystallization temperature of the transparent conductive film range from 150° C. to 210° C. or from 170° C. to 210° C.

### EXAMPLES

In Examples 1 to 3 of Table 1 below, the sputtering targets were composed of indium oxide, tin oxide, and gallium. In the sputtering targets, the content of tin atoms was 9 atomic percent of the total amount of indium and tin atoms, and the content of gallium atoms was 3 to 6 atomic percent of the total amount of indium, tin, and gallium atoms.

The sputtering targets were loaded into a Direct Current (DC) magnetron sputtering apparatus and then transparent conductive films were formed over glass substrates. In this case, the sputtering was performed at a substrate temperature of 100° C. in a mixture atmosphere in which a small amount of oxygen gas was mixed with argon gas. As a result, the transparent conductive films having a thickness of about 800 Å were produced.

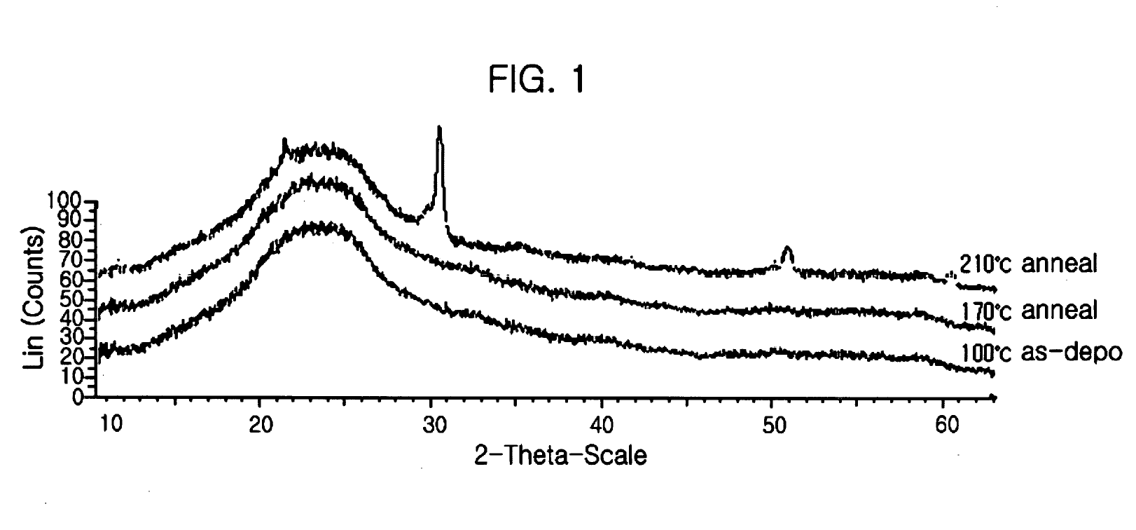

As a result of XRD analysis conducted on Example 2, seen in FIG. 1, no crystalline peak appeared.

In addition, thin films, which were deposited at a substrate temperature of 100° C., were subjected to heat treatment at 170° C. and 210° C. in the air. As a result, no crystalline peak appeared from the thin film that was subjected to heat treatment at 170° C., whereas a crystalline peak appeared from the thin film that was subjected to heat treatment at 210° C. Here, the specific resistances of the thin films were measured to be 2.6×10⁻⁴ Ωcm.

### Comparative Example 1

A sputtering target of Comparative Example 1 was made of indium oxide and tin oxide, in which the content of tin atoms was 9 atomic percent of the total amount of indium atoms and tin atoms.

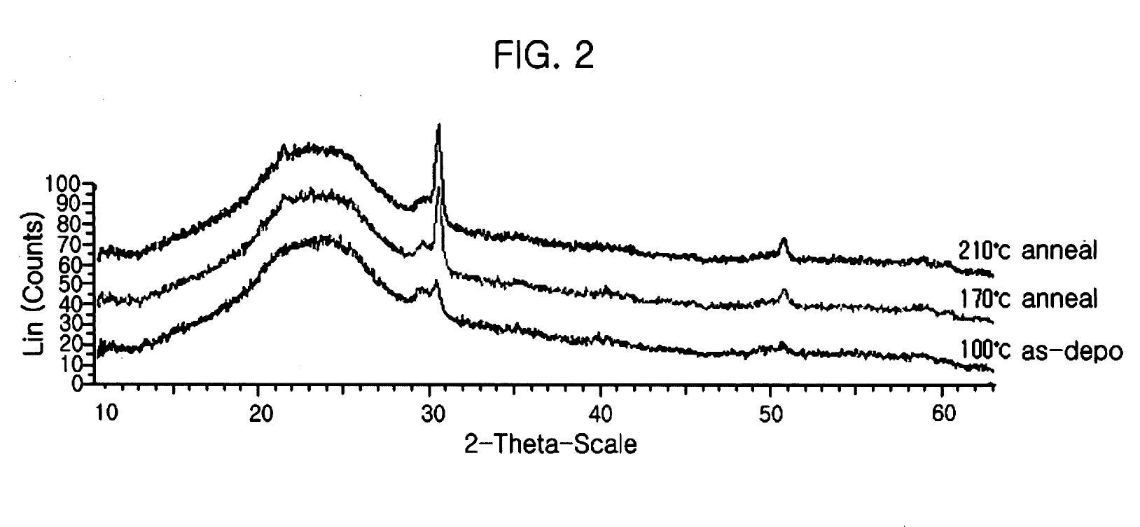

Transparent conductive films were fabricated and heat treated under the same conditions as in the above-described Examples. As a result of XRD analysis shown in FIG. 2, a crystalline peak appeared from the thin films that were heat treated not only at 170° C. and 210° C., but also at 100° C.

### Comparative Example 2

A sputtering target of Comparative Example 2 was made of indium oxide and zinc oxide, in which the content of zinc atoms was 17 atomic percent of the total amount of indium atoms and zinc atoms.

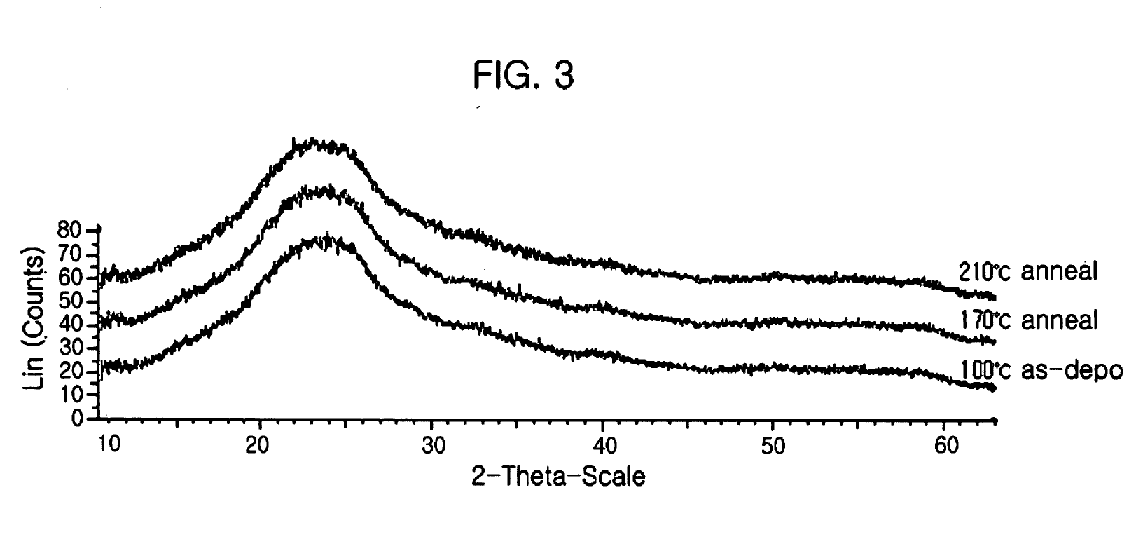

Transparent conductive films were fabricated and heat treated under the same conditions as in the above-described Examples. As a result of XRD analysis shown in FIG. 3, it could be seen that no crystalline peak appeared from the thin films that were heat treated not only at 170° C. and 210° C., but also at 100° C.

Table 1 below presents the results obtained by measuring light transmissivity, specific resistance, and film crystallization temperature from the above-mentioned Examples and Comparative Examples.

TABLE 1

| | | Light | | Specific resistance | | |
|---|---|---|---|---|---|---|
| | Type and | transmissivity (%) | | (×10⁻⁴ Ω · cm) | | |
| | content | Film | Heat | Film | Heat | Film |
| | of dopant | formed at | treated | formed at | treated | crystallization |
| | (at %) | 100° C. | at 210° C. | 100° C. | at 210° C. | temp (° C.) |
| Example 1 | Ga 3.5 | 81.3 | 86.5 | 9.64E−04 | 2.82E−04 | 170 to 210 |
| Example 2 | Ga 4 | 81.7 | 86.3 | 9.42E−04 | 2.65E−04 | 170 to 210 |
| Example 3 | Ga 4.5 | 80.8 | 86.1 | 9.71E−04 | 2.83E−04 | 170 to 210 |
| Comp. | None | 84.4 | 87.1 | 4.94E−04 | 2.79E−04 | 100 or less |
| example 1 | | | | | | |
| Comp. | None | 84.2 | 84.2 | 3.50E−04 | 3.45E−04 | 210 or more |
| example 2 | | | | | | |

When compared with the Examples, the ITO transparent conductive films of comparative example 1 exhibit the result of bad etchability due to the very low film crystallization temperature. In addition, the IZO transparent conductive films of Comparative Example 2 exhibit inferior light transmissivity and specific resistance characteristics although the film crystallization temperature is not low.

In contrast, it can be appreciated that the transparent conductive films of Examples of the invention, which were heat treated at 210° C., exhibit improved light transmissivity and lowered specific resistivity when compared to the transparent conductive films formed at 100° C.

The transparent conductive films fabricated using the sputtering target according to exemplary embodiments of the invention can be applied in a variety of fields, and exhibit characteristics that make them particularly suitable for use as transparent electrodes for LCDs.

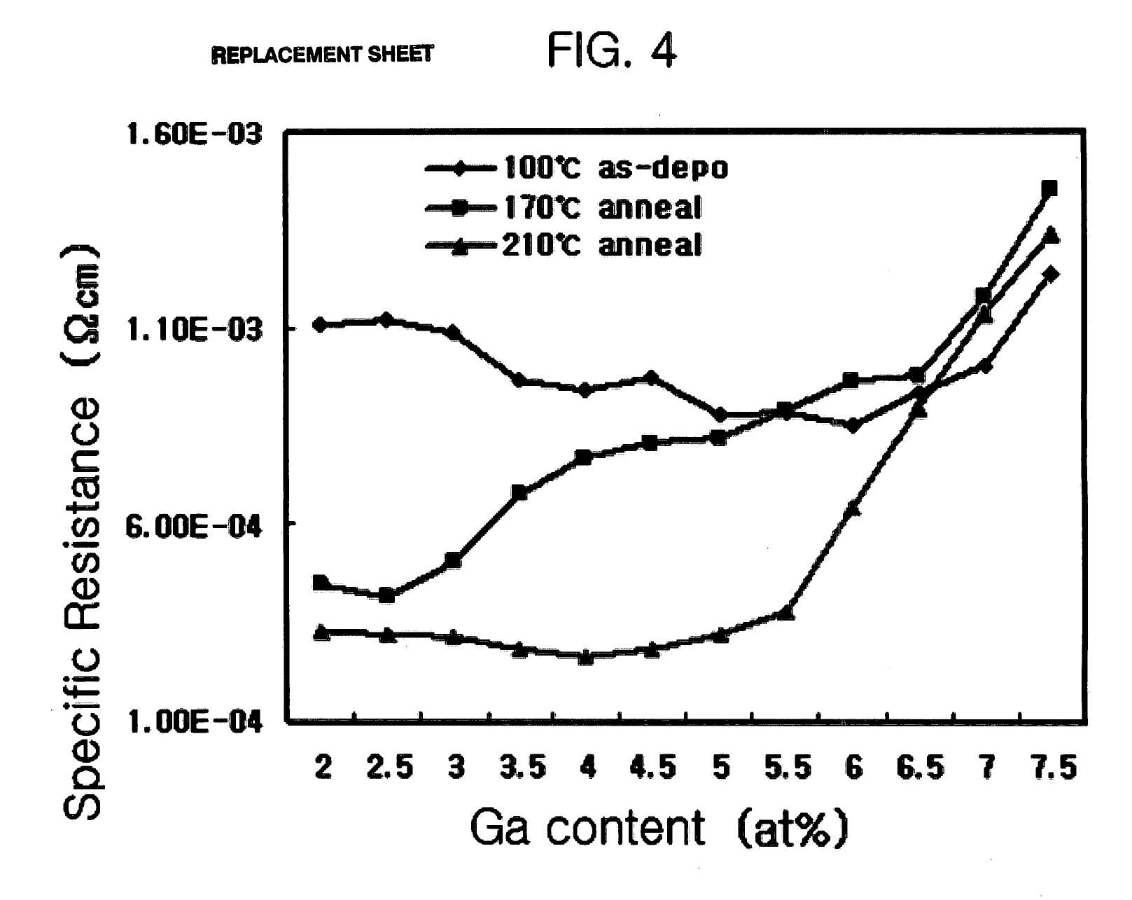

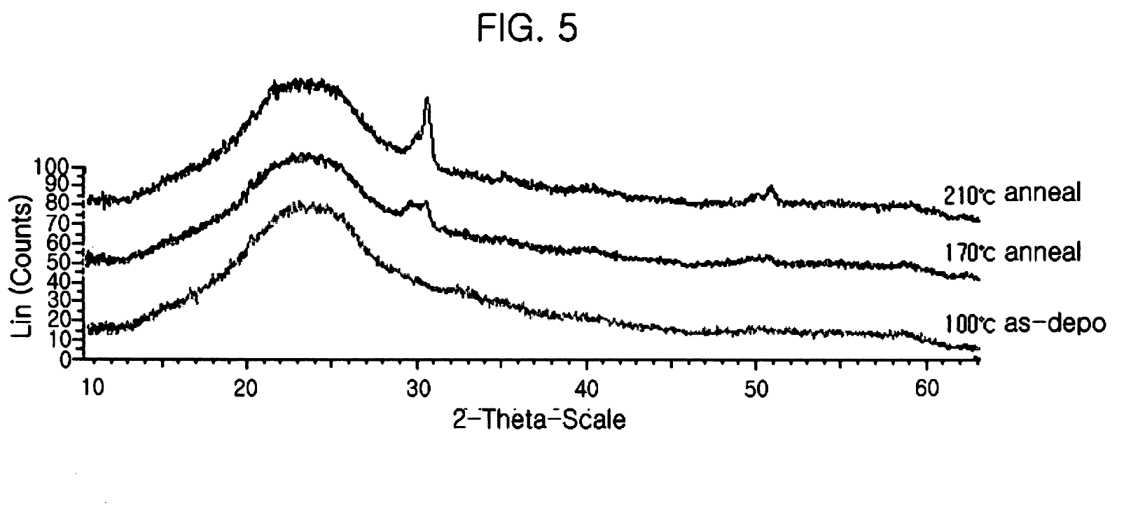

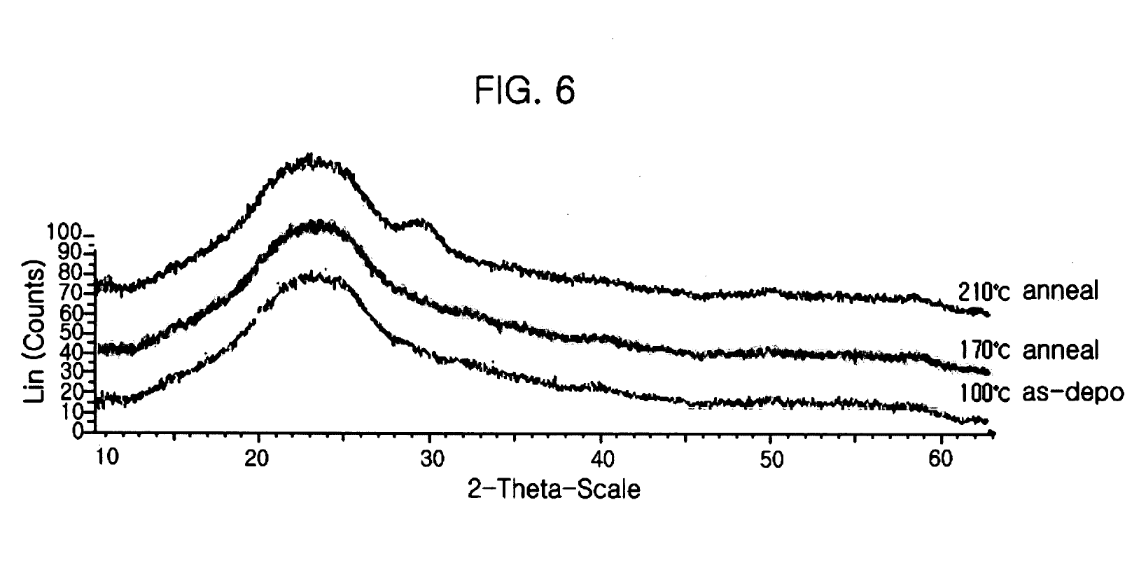

FIG. 4 is a graph showing the change in the specific resistances of transparent conductive films depending on the contents of gallium in ITO sputtering targets, FIG. 5 is a graph showing the result of XRD analysis on a transparent conductive film fabricated from a target that contains 3 atomic percent of gallium, and FIG. 6 is a graph showing an XRD analysis result of a transparent conductive film fabricated from a target that contains 6.5 atomic percent of gallium.

As shown in the figures, it can be appreciated that, if the content of gallium is less than 3 atomic percent, the crystallization temperature is lowered to 170° C. or less, so that a crystalline peak is also detected at 170° C. (see FIG. 5). If the content of gallium exceeds 6.5 atomic percent, no crystallization occurs even at 210° C. (see FIG. 6), thereby resulting in high specific resistance.

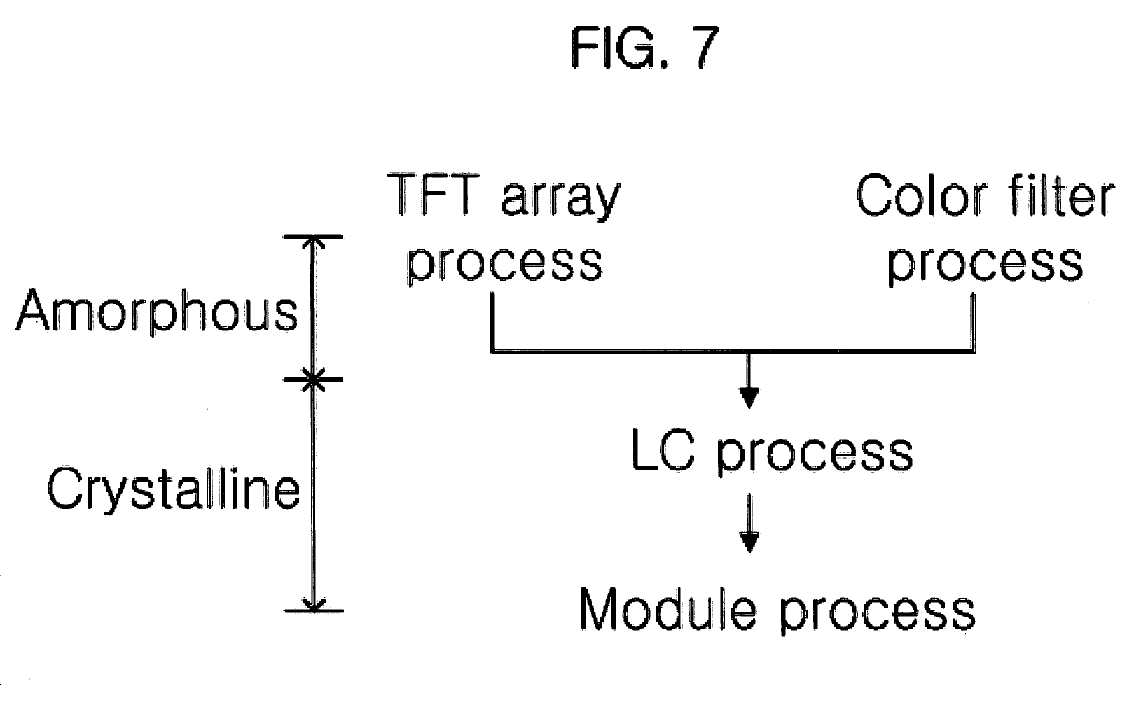

In general, referring to FIG. 7, an LCD is fabricated through a Thin Film Transistor (TFT) array process, a color filter process, a liquid crystal process, and a module process.

In the TFT array process, transparent electrodes are deposited and patterned. The TFT array process is performed at a temperature typically below 150° C. or 170° C. After the fabrication of a TFT array substrate and a color filter substrate is completed, subsequent processes, such as the liquid crystal process, are performed. At least part of the subsequent processes is performed at a temperature typically ranging from 150° C. to 210° C. or from 170° C. to 210° C.

Therefore, when the temperature in which the TFT array process is performed is called a first temperature (e.g., below 170° C.) and the temperature in which the subsequent processes are performed is called a second temperature (e.g., from 170° C. to 210° C.), significant advantages, such as patterning processability, optical characteristics, electrical characteristics, or the like, can be realized if the transparent electrodes remain in the amorphous state at the first temperature and are phase-transformed into the crystalline state at the second temperature.

That is, it is possible to ensure that the transparent electrodes remain in the amorphous state during the TFT array process in order to maximize etchability, and after the etching is completed, are phase-transformed into the crystalline state during the subsequent process in order to maximize light transmissivity, conductivity, and durability.

Describing in more detail, a TFT array substrate is fabricated by depositing an amorphous transparent conductive film through sputtering at a first temperature, and then patterning the deposited amorphous transparent film by etching it using a weak acid. In the subsequent process, the patterned amorphous transparent conductive film is crystallized at a second temperature higher than the first temperature.

The subsequent process can inherently provide the second temperature in the fabrication process of an LCD. In an alternative embodiment, separate heat treatment step can, of course, be performed for crystallization only.

The foregoing descriptions of specific exemplary embodiments of the present invention have been presented for the purposes of illustration and description. They are not intended to be exhaustive or to limit the invention to the precise forms disclosed, and obviously many modifications and variations are possible in light of the above teachings. The exemplary embodiments were chosen and described in order to explain certain principles of the invention and their practical application, to thereby enable others skilled in the art to make and utilize various exemplary embodiments of the present invention, as well as various alternatives and modifications thereof. It is intended that the scope of the invention be defined by the Claims appended hereto and their equivalents.

What is claimed is:

1. An indium tin oxide sputtering target comprising indium oxide, tin oxide, and gallium,
wherein a content of tin atoms is 5 to 15 atomic percent of a total amount of indium and tin atoms, and
wherein a content of gallium atoms is 0.5 to 7 atomic percent of a total amount of indium, tin, and gallium atoms.

2. The indium tin oxide sputtering target according to claim 1, wherein the content of tin atoms is 7 to 10 atomic percent of the total amount of indium and tin atoms.

3. The indium tin oxide sputtering target according to claim 2, wherein the content of tin atoms is 9 to 10 atomic percent of the total amount of indium and tin atoms.

4. The indium tin oxide sputtering target according to claim 1, wherein the content of gallium atoms is 3 to 6.5 atomic percent of the total amount of indium, tin, and gallium atoms.

5. The indium tin oxide sputtering target according to claim 1, comprising a sputtering target for depositing a transparent electrode for a liquid crystal display.

6. A method of fabricating an indium tin oxide transparent conductive film, comprising depositing the transparent conductive film by sputtering a sputtering target, wherein the sputtering target comprises indium oxide, tin oxide, and gallium, wherein a content of tin atoms is 5 to 15 atomic percent of a total amount of indium and tin atoms, and wherein a content of gallium atoms is 0.5 to 7 atomic percent of a total amount of indium, tin, and gallium atoms.

7. The method according to claim 6, comprising depositing an amorphous transparent conductive film by sputtering the sputtering target at a first temperature.

8. The method according to claim 7, comprising patterning the deposited amorphous transparent conductive film by etching it using a weak acid.

9. The method according to claim 8, comprising crystallizing the patterned amorphous transparent conductive film at a second temperature higher than the first temperature.

10. An indium tin oxide transparent conductive film deposited by sputtering a sputtering target, wherein the sputtering target comprises indium oxide, tin oxide, and gallium, wherein a content of tin atoms is 5 to 15 atomic percent of a total amount of indium and tin atoms, and wherein a content of gallium atoms is 0.5 to 7 atomic percent of a total amount of indium, tin, and gallium atoms, and wherein a crystallization temperature ranges from 150° C. to 210° C.

11. The indium tin oxide transparent conductive film according to claim 10, wherein the crystallization temperature ranges from 170° C. to 210° C.

12. The indium tin oxide transparent conductive film according to claim 10, comprising a transparent electrode for a liquid crystal display.

13. A liquid crystal display comprising a transparent electrode made of an indium tin oxide transparent conductive film deposited by sputtering a sputtering target, wherein the sputtering target comprises indium oxide, tin oxide, and gallium, wherein a content of tin atoms is 5 to 15 atomic percent of a total amount of indium and tin atoms, and wherein a content of gallium atoms is 0.5 to 7 atomic percent of a total amount of indium, tin, and gallium atoms, and wherein a crystallization temperature ranges from 150° C. to 210° C.
